(19) United States
(12) Patent Application Publication
(10) Pub. No.: US 2021/0294190 A1
(43) Pub. Date: Sep. 23, 2021

(54) LIGHTING DEVICE AND PROJECTION DISPLAY DEVICE

(71) Applicant: SONY CORPORATION, TOKYO (JP)

(72) Inventor: NORIKO TSUCHIYA, TOKYO (JP)

(21) Appl. No.: 17/250,567

(22) PCT Filed: Jul. 4, 2019
(86) PCT No.: PCT/JP2019/026623

§ 371 Date: Feb. 3, 2021

(30) Foreign Application Priority Data
Aug. 10, 2018 (JP) 2018-151483

(51) Int. Cl. G03B 21/16; H05K 7/20; G03B 21/20

(52) U.S. Cl. CPC G03B 21/16; G03B 21/2033; G03B 21/2013; H05K 7/2039

(57) ABSTRACT

Provided is a lighting device capable of detecting a temperature of a light emitting element more accurately. Specifically, provided is a lighting device including two or more light emitting units, in which the light emitting units each include: a light emitting element including a heat radiating surface; a metal plate arranged to face the heat radiating surface of the light emitting element and provided with a recessed portion at a position corresponding to the heat radiating surface of the light emitting element; and a wiring board arranged inside the recessed portion and provided with a temperature detection unit.

### TECHNICAL FIELD

The present technology relates to a lighting device and a projection display device including the lighting device.

### BACKGROUND ART

In a projection display device such as a projector, it is necessary to perform output control of a light emitting element to guarantee the illuminance. Since the light emitting element generates heat due to light emission and the output decreases as the temperature rises, it is necessary to cool the light emitting element and control the current value using the temperature of the light emitting element as an index. For example, in Patent Document 1, a technology is described in which in an image display device including a red laser light source device, a green laser light source device, and a blue laser light source device, a large amount of cooling air is sent to the red laser light source device to suppress a temperature rise, and a temperature sensor is provided for detecting the temperature of the red laser light source device.

### CITATION LIST

### Patent Document

Patent Document 1: Japanese Patent Application Laid-Open No. 2013-11841

### SUMMARY OF THE INVENTION

### Problems to be Solved by the Invention

With the technology described in Patent Document 1, there is a possibility that the temperature cannot be accurately detected for the light source device that is not provided with a temperature sensor, other than the red laser light source device. For this reason, temperature control of the light source device cannot be appropriately performed, and there is a possibility that the output decreases due to the temperature rise.

Thus, a main object of the present technology is to provide a lighting device capable of detecting the temperature of the light emitting element more accurately.

### Solutions to Problems

That is, the present technology provides

a lighting device including

two or more light emitting units, in which

the light emitting units each include:

a light emitting element including a heat radiating surface;

a metal plate arranged to face the heat radiating surface of the light emitting element and provided with a recessed portion at a position corresponding to the heat radiating surface of the light emitting element; and

a wiring board arranged inside the recessed portion and provided with a temperature detection unit.

The light emitting unit may include a first heat conductive layer provided between the heat radiating surface of the light emitting element and the metal plate.

The lighting device may include a heat sink, and

the light emitting unit may include a second heat conductive layer provided between the metal plate and the heat sink.

The lighting device may include a heat sink, and

the light emitting unit may include a third heat conductive layer provided surrounded by the metal plate, the wiring board, and the heat sink.

The lighting device may include two or more each of red light emitting units each including a red light emitting element, green light emitting units each including a green light emitting element, and blue light emitting units each including a blue light emitting element.

The red light emitting units, the green light emitting units, and the blue light emitting units may be arranged separately on two or more planes.

Furthermore, the present technology provides

a projection display device including

a lighting device and a projection device, in which

the lighting device includes two or more light emitting units, in which

the light emitting units each include:

a light emitting element including a heat radiating surface;

a metal plate arranged to face the heat radiating surface of the light emitting element and provided with a recessed portion at a position corresponding to the heat radiating surface of the light emitting element; and

a wiring board arranged inside the recessed portion and provided with a temperature detection unit.

### Effects of the Invention

According to the present technology, it is possible to obtain a lighting device for a projection display device capable of detecting the temperature of the light emitting element more accurately. Note that, the effect of the present technology is not necessarily limited to the effect described here, and can be any effect described in the present specification.

### BRIEF DESCRIPTION OF DRAWINGS

FIG. 1 is a schematic diagram illustrating a part of a configuration of a projection display device 100 according to an embodiment of the present technology.

FIG. 2 is a perspective view of a part of a lighting device 1 as viewed from a direction of an arrow D₂ in FIG. 1B.

FIG. 3 is a schematic sectional view of the lighting device 1 according to the embodiment of the present technology.

FIG. 4 is a schematic diagram of a cross section taken along a line A-A of the lighting device 1 illustrated in FIG. 3, as viewed in the arrow direction.

FIG. 5 is a sectional view schematically illustrating the periphery of a light emitting element 911 in a lighting device 910 of a conventional technology.

FIG. 6 is a flow diagram illustrating a thermal path in the lighting device 910 of the conventional technology.

FIG. 7 is a flow diagram illustrating a thermal path in the lighting device 1 of the present technology.

FIG. 8 is a schematic sectional view of the lighting device 1 including a first screw 31 and a second screw 32.

### MODE FOR CARRYING OUT THE INVENTION

Hereinafter, a preferred embodiment for carrying out the present technology will be described with reference to the drawings. Note that, the embodiments described below are representative embodiments of the present technology, and the scope of the present technology should not be construed narrowly. The description will be made in the following order.

1. Configuration of projection display device

2. Configuration of lighting device

3. Comparison between present technology and conventional technology

(1) Thermal path and detection temperature

(2) Current value control

(3) Heat radiation performance

<1. Configuration of Projection Display Device>

A configuration of a projection display device according to the present technology will be described.

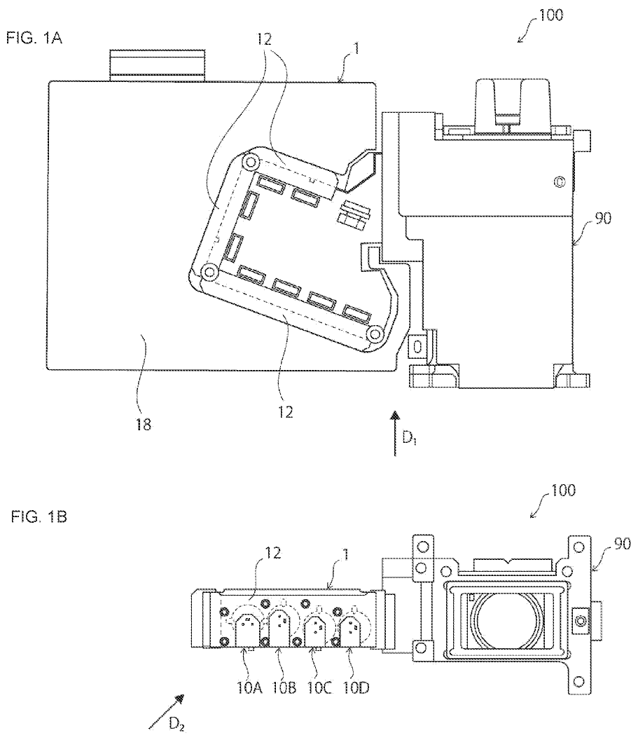

FIG. 1 is a schematic diagram illustrating a part of a configuration of a projection display device 100 according to an embodiment of the present technology. FIG. 1A is a plan view of a lighting device 1 and a projection device 90 included in the projection display device 100, and FIG. 1B is a front view of the lighting device 1 and the projection device 90 as viewed from a direction of an arrow Di in FIG. 1A. In FIG. 1B, illustration is omitted of a heat sink 18 illustrated in FIG. 1A.

As illustrated in FIGS. 1A and 1B, the projection display device 100 includes the lighting device 1 and the projection device 90. Although illustration is omitted, the lighting device 1 and the projection device 90 are housed inside a housing of the projection display device 100 together with other members such as a power supply unit and a cooling unit. The projection display device 100 is, for example, a projector.

As illustrated in FIG. 1A, the lighting device 1 includes a metal plate 12 and the heat sink 18. Furthermore, as illustrated in FIG. 1B, the lighting device 1 includes two or more light emitting units 10 each including a light emitting element and the like. FIG. 1B illustrates four light emitting units 10 (light emitting units 10A, 10B, 10C, 10D). A configuration of the lighting device 1 will be described in detail later.

The projection device 90 projects image light emitted from the lighting device 1 onto an object such as a screen. The projection device 90 includes, for example, a plurality of lenses and the like.

<2. Configuration of Lighting Device>

The configuration of the lighting device according to the present technology will be described.

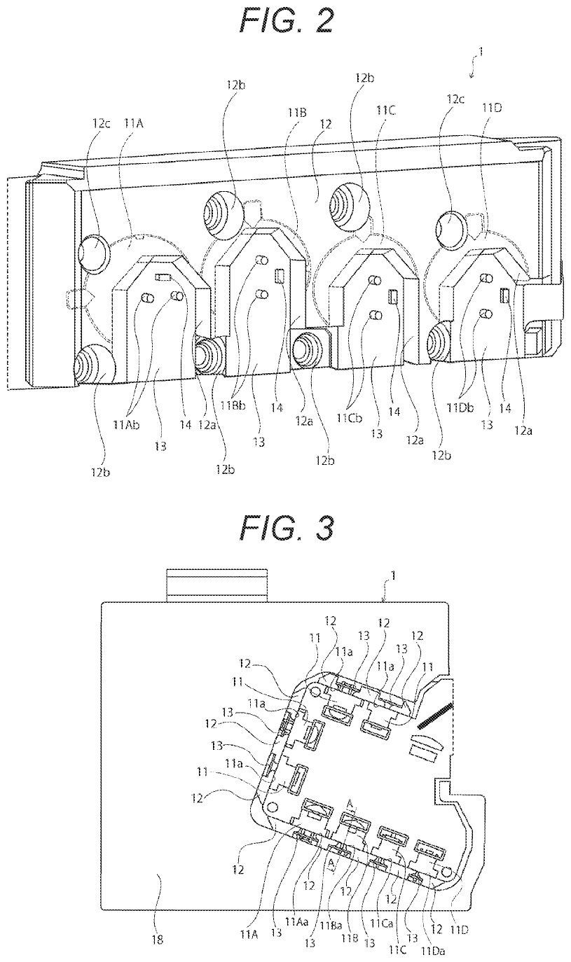

FIG. 2 is a perspective view of a part of the lighting device 1 as viewed from a direction of an arrow D₂ in FIG. 1B. FIG. 3 is a schematic sectional view of the lighting device 1 according to the embodiment of the present technology. As illustrated in FIGS. 2 and 3, the lighting device 1 includes a light emitting element 11, the metal plate 12, a wiring board 13, and a temperature detection unit 14.

FIG. 2 illustrates four light emitting elements 11 (light emitting elements 11A, 11B, 11C, 11D). Each of the light emitting elements 11 (light emitting elements 11A, 11B, 11C, 11D) includes terminals 11b (terminals 11Ab, 11Bb, 11Cb, 11Db). As illustrated in FIG. 3, the light emitting element 11 (light emitting element 11A, 11B, 11C, 11D) includes a heat radiating surface 11a (heat radiating surface 11Aa, 11Ba, 11Ca, 11Da) for radiating heat generated by light emission, to the metal plate 12 and the like. The light emitting element 11 is preferably a laser diode. Examples of the light emitting element 11 include light emitting elements that emit visible light such as a red light emitting element that emits red light, a green light emitting element that emits green light, and a blue light emitting element that emits blue light. Furthermore, as the light emitting element 11, a light emitting element that emits infrared rays can also be used. The light emitting element that emits infrared rays can be used for sensing. Wavelength bands of the light emitted from the respective plurality of light emitting elements 11 may be the same or different.

The metal plate 12 is arranged to face the heat radiating surface 11a of the light emitting element 11. The metal plate 12 may be directly in contact with the heat radiating surface 11a of the light emitting element 11, or may be indirectly in contact with it via a first heat conductive layer described later. The heat emitted from the heat radiating surface 11a of the light emitting element 11 is transferred to the metal plate 12.

The metal plate 12 includes a recessed portion 12a at a position corresponding to the heat radiating surface 11a of the light emitting element 11. The wiring board 13 is arranged inside the recessed portion 12a. A shape of the recessed portion 12a is preferably a shape that follows a part of the outer shape of the wiring board 13 so that the inner wall surface is in contact with the wiring board. As a material used for the metal plate 12, a metal having high thermal conductivity is preferable, and examples of the material include aluminum, aluminum alloy, zinc, zinc alloy, magnesium, magnesium alloy, copper, copper alloy, gold, gold alloy, silver, silver alloy, and the like. The metal plate 12 may include one plate, or may include a combination of two or more plates.

The metal plate 12 can include a first screw hole 12b. A first screw for screwing the metal plate 12 to a holding unit that holds the light emitting element 11 is inserted into the first screw hole 12b. By fastening the first screw to bring the metal plate 12 and the holding unit close to each other, it is possible to improve transfer efficiency of the heat emitted from the light emitting element 11. Furthermore, the metal plate 12 can include a second screw hole 12c. A second screw for screwing together the heat sink 18, the metal plate 12, and the holding unit that holds the light emitting element 11 is inserted into the second screw hole 12c. By fastening the second screw to bring the heat sink 18, the metal plate 12, and the holding unit close to each other, it is possible to improve the transfer efficiency of the heat emitted from the light emitting element 11.

The wiring board 13 is arranged inside the recessed portion 12a of the metal plate 12. For this reason, the wiring board 13 is arranged at a position corresponding to the heat radiating surface 11a of the light emitting element 11. The wiring board 13 is provided with holes, and the terminals 11b of the light emitting element 11 penetrates the holes. The wiring board 13 is electrically connected to the terminals 11b, and a signal for driving the light emitting element 11 is transmitted to the terminals 11b via the wiring board 13.

The temperature detection unit 14 is provided at a position corresponding to the light emitting element 11 on the outside surface of the wiring board 13. Examples of the temperature detection unit 14 include a thermistor. The temperature detection unit 14 is used to detect a temperature of the light emitting element 11.

The light emitting unit 10 (light emitting unit 10A, 10B, 10C, 10D) illustrated in FIG. 1 includes the light emitting element 11, the metal plate 12, the wiring board 13, and the temperature detection unit 14 described with reference to FIGS. 2 and 3. Since the lighting device 1 of the present technology includes at least one temperature detection unit 14 for one light emitting element 11, it is possible to individually detect temperatures of the plurality of light emitting elements 11 existing. The lighting device 1 can therefore control current values of the light emitting elements 11 individually depending on the temperatures of the light emitting elements 11 and perform appropriate current value setting. As a result, the lighting device 1 can suppress a decrease in the life and a decrease in the illuminance of the light emitting element 11.

The lighting device 1 of the present technology can include a current control unit (not illustrated) that individually controls the current values of two or more light emitting elements 11 depending on the temperatures of the respective light emitting elements 11. Furthermore, the lighting device 1 can also include a cooling unit (not illustrated) for suppressing a temperature rise of the light emitting element 11 depending on the temperature of the light emitting element 11. The cooling unit is, for example, a fan or the like.

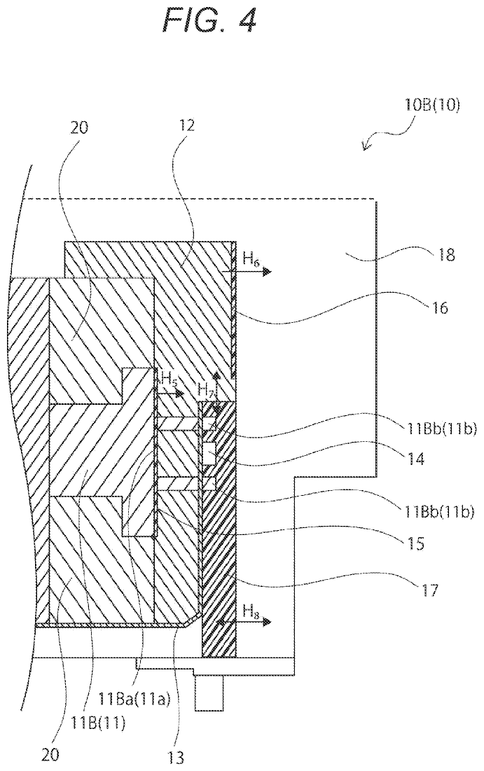

Furthermore, the light emitting unit 10 of the lighting device 1 preferably further includes at least one heat conductive layer selected from the first heat conductive layer, a second heat conductive layer, and a third heat conductive layer. Hereinafter, the light emitting unit 10 including the heat conductive layer will be described with reference to FIG. 4.

FIG. 4 is a schematic diagram of a cross section taken along a line A-A of the lighting device 1 illustrated in FIG. 3, as viewed in the arrow direction. That is, FIG. 4 illustrates a cross section of the light emitting unit 10B included in the lighting device 1 of FIG. 3, and the light emitting element 11B of the light emitting unit 10B is held by a holding unit 20. Note that, since the light emitting unit 10B illustrated in FIG. 4 is an example of the light emitting unit 10, hereinafter, the description will be given by replacing the light emitting unit 10B in FIG. 4 with the light emitting unit 10.

FIG. 4 illustrates, as an example, the light emitting unit 10 including a first heat conductive layer 15, a second heat conductive layer 16, and a third heat conductive layer 17. The first heat conductive layer 15 is provided between the heat radiating surface 11a of the light emitting element 11 and the metal plate 12. The second heat conductive layer 16 is provided between the metal plate 12 and the heat sink 18. The third heat conductive layer 17 is provided to be surrounded by the metal plate 12, the wiring board 13, and the heat sink 18.

The light emitting unit 10 preferably includes at least one heat conductive layer selected from the first heat conductive layer 15, the second heat conductive layer 16, and the third heat conductive layer 17. The light emitting unit 10 more preferably includes at least two heat conductive layers selected from the first heat conductive layer 15, the second heat conductive layer 16, and the third heat conductive layer 17. The light emitting unit 10 further preferably includes the first heat conductive layer 15, the second heat conductive layer 16, and the third heat conductive layer 17.

The thickness of the first, second, and third heat conductive layers is preferably thin from a viewpoint of reducing a heat transfer loss. The thickness of the first heat conductive layer 15 and the second heat conductive layer is preferably 10 to 100 μm, more preferably 30 to 70 μm. The thickness of the first heat conductive layer 15 and the thickness of the second heat conductive layer 16 may be the same or different. Furthermore, the thickness of the third heat conductive layer 17 is preferably thicker than that of the temperature detection unit 14 on the wiring board 13, and can be, for example, 0.8 to 1.6 mm.

The first, second, and third heat conductive layers include, for example, thermally conductive grease or the like. Materials used for the respective heat conductive layers may be the same or different.

The first heat conductive layer 15 fills an interface between the light emitting element 11 and the metal plate 12 to increase the heat transfer efficiency. The second heat conductive layer 16 fills an interface between the metal plate 12 and the heat sink 18 to increase the heat transfer efficiency. The third heat conductive layer 17 fills a gap surrounded by the metal plate 12, the wiring board 13, and the heat sink 18 to increase the heat transfer efficiency. With such a configuration, the lighting device 1 of the present technology can further reduce a transfer loss of the heat emitted from the light emitting element 11.

<3. Comparison Between Present Technology and Conventional Technology>

The present technology will be further described in comparison with a conventional technology.

(1) Thermal Path and Detection Temperature

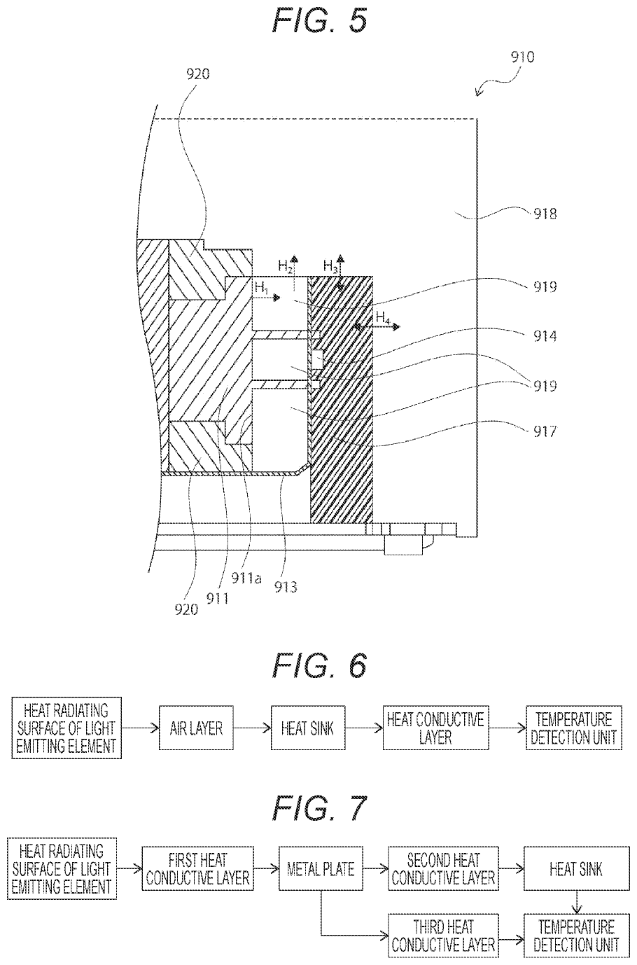

The lighting device of the present technology and the conventional technology are compared with each other regarding a path of the heat emitted from the light emitting element transferred to the temperature detection unit, and a detection temperature detected by the temperature detection unit. First, a lighting device 910 of the conventional technology will be described with reference to FIGS. 5 and 6, and then the lighting device 1 of the present technology will be described with reference to FIGS. 4 and 7.

FIG. 5 is a sectional view schematically illustrating the periphery of a light emitting element 911 in the lighting device 910 of the conventional technology. The light emitting element 911 including a laser diode is held by a holding unit 920. The light emitting element 911 includes a heat radiating surface 911a. A wiring board 913 is provided on the heat radiating surface 911a side of the light emitting element 911 at a distance from the heat radiating surface 911a. An air layer 919 exists in a gap surrounded by the heat radiating surface 911a of the light emitting element 911, the wiring board 913, and a heat sink 918. A heat conductive layer 917 including thermally conductive grease is provided between the wiring board 913 and the heat sink 918. The heat conductive layer 917 is often provided to have a thickness of about 3 mm. The wiring board 913 includes a temperature detection unit 914 including a thermistor on the outside (heat sink 918 side) surface.

Heat emitted from the heat radiating surface 911a of the light emitting element 911 is transferred to the air layer 919 as illustrated by an arrow H₁, and is transferred from the air layer 919 to the heat sink 918 as illustrated by an arrow H₂. Furthermore, heat transfer is also performed between the heat conductive layer 917 and the heat sink 918, indicated by arrows H₃ and H₄.

FIG. 6 is a flow diagram illustrating a thermal path in the lighting device 910 of the conventional technology. As illustrated in FIG. 6, the heat emitted from the heat radiating surface 911a of the light emitting element 911 is transferred to the temperature detection unit 914 via the air layer 919, the heat sink 918, and the heat conductive layer 917. As described above, since the heat passes through the air layer 919, the heat transfer loss is large in the lighting device 910 of the conventional technology. Furthermore, the fact that the heat conductive layer 917 is thick also contributes to the heat transfer loss. As a result, a temperature difference between the light emitting element 911 and a thermal environment around the temperature detection unit 914 is large, and it is difficult to accurately detect a temperature of the light emitting element 911 in the temperature detection unit 914.

In a verification conducted by the present inventor, a result has been obtained that the temperature detected by the temperature detection unit 914 is up to 7° C. lower than an actual temperature of the light emitting element 911, under an environment of 25° C. Note that, a difference between the temperature of the light emitting element 911 and the temperature detected by the temperature detection unit 914 varies depending on an environmental temperature, a wavelength of light emitted by the light emitting element 911, and the like.

Next, referring back to FIG. 4, the lighting device 1 of the present technology will be described. The heat emitted from the heat radiating surface 11a of the light emitting element 11 is transferred to the metal plate 12 via the first heat conductive layer 15 as illustrated by an arrow H₅, and is transferred from the metal plate 12 to the heat sink 18 via the second heat conductive layer 16 as illustrated by an arrow H₆. Furthermore, heat transfer is also performed between the metal plate 12 and the third heat conductive layer 17, indicated by an arrow H₇, and between the third heat conductive layer 17 and the heat sink 18, indicated by an arrow H₈.

FIG. 7 is a flow diagram illustrating a thermal path in the lighting device 1 of the present technology. As illustrated in FIG. 7, the heat emitted from the heat radiating surface 11a of the light emitting element 11 is transferred to the temperature detection unit 14 via a path passing through the first heat conductive layer 15, the metal plate 12, the second heat conductive layer 16, and the heat sink 18, and a path passing through the first heat conductive layer 15, the metal plate 12, and the third heat conductive layer 17.

The metal plate 12 having high thermal conductivity is arranged in this way, whereby the transfer loss of the heat emitted from the light emitting element 11 is reduced. Furthermore, since the first heat conductive layer 15, the second heat conductive layer 16, and the third heat conductive layer 17 are formed thinner than the conventional heat conductive layer 917 (FIG. 5), the heat transfer loss is further reduced. As a result, a temperature difference between the light emitting element 11 and a thermal environment around the temperature detection unit 14 is small, and it is possible to detect the temperature of the light emitting element 11 more accurately in the temperature detection unit 14.

In a verification conducted by the present inventor, it has been confirmed that the temperature of the light emitting element 11 can be detected more accurately than in the conventional technology since a deviation between an actual temperature of the light emitting element 11 and the temperature detected by the temperature detection unit 14 is suppressed to about 1° C. at the maximum, under an environment of 25° C.

(2) Current Value Control

Current value control in the lighting device of the present technology will be described in comparison with the conventional technology.

As an example, a lighting device will be described that includes a red light emitting unit including a red laser diode, a green light emitting unit including a green laser diode, and a blue light emitting unit including a blue laser diode. In the laser diode of each color, a current value is set that obtains an output closest to a target output in a state where white balance is adjusted according to the target output. At that time, if there is a large deviation between an actual temperature of the laser diode and a detection temperature in the temperature detection unit, a problem may occur. For example, in a case where the actual temperature of the laser diode is higher than the detection temperature in the temperature detection unit, an overcurrent flows through the laser diode, the life of the laser diode is decreased, and in the worst case, the laser diode is destroyed. In a case where the actual temperature of the laser diode is lower than the detection temperature in the temperature detection unit, the current value of the laser diode is set lower than the actually usable current value, and the illuminance decreases.

In the lighting device of the conventional technology, since there is a large deviation between the actual temperature of the light emitting element and the detection temperature of the temperature detection unit as described above, the current value of the laser diode cannot be appropriately controlled, and problems may occur such as the decrease in the life of the laser diode and the decrease in the illuminance. On the other hand, in the lighting device of the present technology, a difference between the actual temperature of the light emitting element and the detection temperature in the temperature detection unit is small, and the temperature of the light emitting element can be detected more accurately, so that the current value of the laser diode can be appropriately controlled. As a result, it is possible to suppress the decrease in the life of the laser diode and the decrease in the illuminance. That is, according to the lighting device of the present technology, the current value control is possible depending on the actual temperature of the light emitting element. Furthermore, according to the lighting device of the present technology, it is possible to suppress the decrease in the life of the laser diode and obtain an appropriate illuminance, so that product performance is improved.

(3) Heat Radiation Performance

Heat radiation performance of the lighting device of the present technology will be described in comparison with the conventional technology.

Generally, in a projection display device, heat generated by light emission of a light emitting element included in a lighting device is transferred to a heat sink, and a fan is used to send wind to the heat sink to perform cooling. To improve the heat radiation performance, it is necessary to efficiently transfer the heat of the light emitting element to the heat sink.

In the lighting device 910 of the conventional technology illustrated in FIG. 5, the air layer 919 and the thick heat conductive layer 917 exist on the heat radiating surface 911a side of the light emitting element 911. For this reason, heat transfer is poor from the heat radiating surface 911a of the light emitting element 911 to the heat sink 918, and heat is trapped, which may result in inferior heat radiation performance.

On the other hand, the lighting device 1 of the present technology illustrated in FIG. 4 includes the metal plate 12 having high thermal conductivity and a wide contact area with the heat sink 18. For this reason, the heat emitted from the heat radiating surface 11a of the light emitting element 11 is diffused to the metal plate 12 and then efficiently transferred to the heat sink 18. Furthermore, since the first heat conductive layer 15, the second heat conductive layer 16, and the third heat conductive layer 17 existing on the thermal path are thinner than the conventional heat conductive layer, the heat transfer loss can be suppressed, and heat transfer to the heat sink 18 can be made efficient. That is, according to the lighting device 1 of the present technology, it is possible to improve the heat radiation performance as compared with the conventional case.

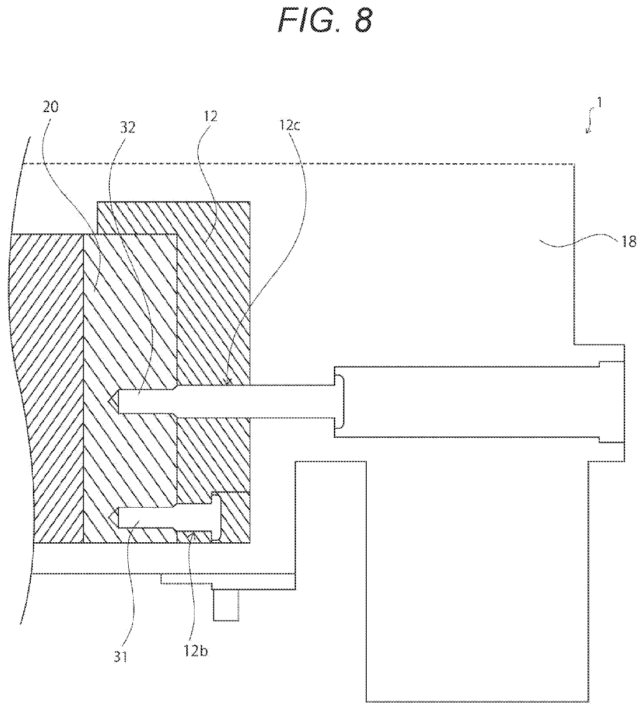

Next, the configuration of the lighting device 1 of the present technology will be further described with reference to FIG. 8. FIG. 8 is a schematic sectional view of the lighting device 1 including a first screw 31 and a second screw 32. To further improve the heat radiation performance, the lighting device 1 of the present technology preferably includes at least one of the first screw 31 that screws the metal plate 12 to the holding unit 20, or the second screws 32 that screws the heat sink 18, the metal plate 12, and the holding unit 20 together. By fastening the first screw 31 and/or the second screw 32, it is possible to bring the members to be screwed together closer to each other, and in a case where a heat conductive layer (not illustrated) exists, it is possible to improve adhesion of the heat transfer layer, so that the heat radiation performance can be further improved. In a case where the lighting device 1 includes the first screw 31, the metal plate 12 includes the first screw hole 12b into which the first screw 31 is inserted, and the holding unit 20 includes a screw hole at a position corresponding to the first screw hole 12b. In a case where the lighting device 1 includes the second screw 32, the metal plate 12 includes the second screw hole 12c into which the second screw 32 is inserted, and the heat sink 18 and the holding unit 20 each include a screw hole at a position correspond to the second screw hole 12c.

As described in detail above, the lighting device of the present technology can appropriately perform the current value control of the light emitting element by detecting the temperature of the light emitting element more accurately. Furthermore, the lighting device of the present technology can efficiently transfer and radiates the heat emitted from the light emitting element.

By the way, the heat emitted from the light emitting element tends to be a problem in a case where a large number of light emitting elements are mounted on the lighting device. In particular, in a small lighting device or a small projection display device, a large number of light emitting elements are often mounted for the purpose of suppressing a decrease in brightness (luminance) and improving output, and it is required to efficiently radiate heat while appropriately managing the light emitting elements.

The lighting device of the present technology includes the temperature detection unit for each light emitting element and can control the current value for each light emitting element depending on the temperature of the light emitting element, and exhibits excellent heat radiation performance due to the thermal path that is made efficient, so that it is suitable in the case where a large number of light emitting elements are mounted. Thus, the lighting device of the present technology is preferably a lighting device including two or more light emitting units, and more preferably a lighting device including two or more each of red light emitting units each including a red light emitting element, green light emitting units each including a green light emitting element, and blue light emitting units each including a blue light emitting element.

In the case of a lighting device that includes a red light emitting unit, a green light emitting unit, and a blue light emitting unit and in which these units are not arranged in the same plane, the cooling environment varies depending on each light emitting unit, so that temperature control for each light emitting element is more important. For this reason, the lighting device of the present technology capable of temperature detection for each light emitting element is particularly suitable for a lighting device in which the red light emitting unit, the green light emitting unit, and the blue light emitting unit are separately arranged in two or more planes. For example, in the lighting device 1 illustrated in FIG. 3, multiple light emitting units are not arranged in the same plane, but are arranged separately in three planes.

Furthermore, the lighting device of the present technology is suitably used for a small projection display device. Examples of the small projection display device include a portable projector, a mobile projector, a video projector, a video camera with a projector, a smartphone, and the like.

Note that, the present technology can also be configured as described below.

[1] A lighting device including

two or more light emitting units, in which

the light emitting units each include:

a light emitting element including a heat radiating surface;

a metal plate arranged to face the heat radiating surface of the light emitting element and provided with a recessed portion at a position corresponding to the heat radiating surface of the light emitting element; and

a wiring board arranged inside the recessed portion and provided with a temperature detection unit.

[2] The lighting device according to [1], in which the light emitting unit includes a first heat conductive layer provided between the heat radiating surface of the light emitting element and the metal plate.
[3] The lighting device according to [1] or [2], further including

a heat sink, in which

the light emitting unit includes a second heat conductive layer provided between the metal plate and the heat sink.

[4] The lighting device according to any one of [1] to [3], further including

a heat sink, in which

the light emitting unit includes a third heat conductive layer provided surrounded by the metal plate, the wiring board, and the heat sink.

[5] The lighting device according to any one of [1] to [4], further including two or more each of red light emitting units each including a red light emitting element, green light emitting units each including a green light emitting element, and blue light emitting units each including a blue light emitting element.
[6] The lighting device according to [5], in which the red light emitting units, the green light emitting units, and the blue light emitting units are arranged separately on two or more planes.
[7] A projection display device including

a lighting device and a projection device, in which

the lighting device includes two or more light emitting units, and

the light emitting units each include:

a light emitting element including a heat radiating surface;

a metal plate arranged to face the heat radiating surface of the light emitting element and provided with a recessed portion at a position corresponding to the heat radiating surface of the light emitting element; and

a wiring board arranged inside the recessed portion and provided with a temperature detection unit.

### REFERENCE SIGNS LIST

1 Lighting device
10 Light emitting unit
11 Light emitting element
11a Heat radiating surface
11b Terminal
12 Metal plate
12a Recessed portion
12b First screw hole
12c Second screw hole
13 Wiring board
14 Temperature detection unit
15 First heat conductive layer
16 Second heat conductive layer
17 Third heat conductive layer
18 Heat sink
20 Holding unit
31 First screw
32 Second screw
90 Projection device
100 Projection display device

1. A lighting device comprising
two or more light emitting units, wherein
the light emitting units each include:
a light emitting element including a heat radiating surface;
a metal plate arranged to face the heat radiating surface of the light emitting element and provided with a recessed portion at a position corresponding to the heat radiating surface of the light emitting element; and
a wiring board arranged inside the recessed portion and provided with a temperature detection unit.

2. The lighting device according to claim 1, wherein the light emitting unit includes a first heat conductive layer provided between the heat radiating surface of the light emitting element and the metal plate.

3. The lighting device according to claim 1, further comprising
a heat sink, wherein
the light emitting unit includes a second heat conductive layer provided between the metal plate and the heat sink.

4. The lighting device according to claim 1, further comprising
a heat sink, wherein
the light emitting unit includes a third heat conductive layer provided surrounded by the metal plate, the wiring board, and the heat sink.

5. The lighting device according to claim 1, further comprising two or more each of red light emitting units each including a red light emitting element, green light emitting units each including a green light emitting element, and blue light emitting units each including a blue light emitting element.

6. The lighting device according to claim 5, wherein the red light emitting units, the green light emitting units, and the blue light emitting units are arranged separately on two or more planes.

7. A projection display device comprising
a lighting device and a projection device, wherein
the lighting device includes two or more light emitting units, and
the light emitting units each include:
a light emitting element including a heat radiating surface;
a metal plate arranged to face the heat radiating surface of the light emitting element and provided with a recessed portion at a position corresponding to the heat radiating surface of the light emitting element; and
a wiring board arranged inside the recessed portion and provided with a temperature detection unit.
